(19) United States
(12) Patent Application Publication
(10) Pub. No.: US 2025/0192014 A1
(43) Pub. Date: Jun. 12, 2025

(54) ELECTRONIC PACKAGE AND MANUFACTURING METHOD THEREOF

(71) Applicant: AaltoSemi Inc., Jiangsu (CN)

(72) Inventors: Yin-Ju CHEN, Jiangsu (CN); Min-Yao CHEN, Jiangsu (CN); Sung-Kun LIN, Jiangsu (CN); Jiun-Hua CHIUE, Jiangsu (CN); Andrew C. CHANG, Jiangsu (CN); Zhen-Hu CHANG, Jiangsu (CN)

(21) Appl. No.: 18/966,741

(22) Filed: Dec. 3, 2024

(30) Foreign Application Priority Data
Dec. 8, 2023 (CN) 202311689540.0

(51) Int. Cl. H01L 23/498; H01L 21/48; H01L 25/065

(52) U.S. Cl. CPC H01L 23/49816; H01L 21/4853; H01L 23/49822; H01L 25/0655

(57) ABSTRACT

A manufacturing method of an electronic package is provided, including: providing a circuit structure having a circuit layer; forming an insulating layer on the circuit structure, wherein the insulating layer has a plurality of first vias; forming a plurality of conductive pillars in the plurality of first vias, and disposing an electronic element on the insulating layer; forming an encapsulation layer, on the insulating layer, covering the electronic element and the plurality of conductive pillars, wherein the encapsulation layer has a plurality of second vias exposing the plurality of conductive pillars; and filling in the second vias with a plurality of conductive materials. The present disclosure further provides an electronic package.

### BACKGROUND

### 1. Technical Field

The present disclosure relates to a semiconductor packaging process, and more particularly, to an electronic package that can reduce the overall thickness and a manufacturing method thereof.

### 2. Description of Related Art

FIG. 1 is a cross-sectional view of a conventional electronic package 1. As shown in FIG. 1, the electronic package 1 includes a circuit structure 11, an insulating layer 12, an electronic element 13, a plurality of conductive pillars 14, an encapsulation layer 15, a conductive trace 16 and an electronic device 17. The insulation layer 12 is disposed on the circuit structure 11. The electronic element 13 is disposed on the insulating layer 12. The encapsulation layer 15 is formed on the insulating layer 12 and covers the electronic element 13. The plurality of conductive pillars 14 are embedded in the insulating layer 12 and the encapsulation layer 15, and their top ends are flush with the encapsulation layer 15. The conductive trace 16 is disposed on the encapsulation layer 15 and electrically connected to the conductive pillars 14. The electronic device 17 is disposed on the conductive trace 16 via a plurality of conductive bumps 18.

However, in the conventional electronic package 1, a gap G between the electronic device 17 and the encapsulation layer 15 cannot be reduced due to the existence of the plurality of conductive bumps 18 and the conductive trace 16, making it difficult for the overall thickness of the electronic package 1 to meet the thinning requirements.

Therefore, there is a need for a solution that addresses the aforementioned shortcomings in the prior art.

### SUMMARY

In view of the aforementioned shortcomings of the prior art, the present disclosure provides an electronic package, which comprises: a circuit structure having a circuit layer; an insulating layer disposed on the circuit structure and having a plurality of first vias exposing the circuit layer; an electronic element disposed on the insulating layer and electrically connected to the circuit structure; a plurality of conductive pillars formed in the plurality of first vias and partially protruding from the insulating layer; an encapsulation layer formed on the insulating layer and covering the electronic element and the plurality of conductive pillars, the encapsulation layer having a plurality of second vias exposing the plurality of conductive pillars; and a plurality of conductive materials filled in the plurality of second vias and partially protruding from the encapsulation layer.

The present disclosure also provided a method of manufacturing an electronic package, the method comprises: providing a circuit structure with a circuit layer; forming an insulating layer on the circuit structure, wherein the insulating layer has a plurality of first vias exposing the circuit layer; forming a plurality of conductive pillars in the plurality of first vias, and disposing an electronic element on the insulating layer, so that the plurality of conductive pillars partially protrude from the insulating layer, and the electronic element is electrically connected to the circuit structure; forming an encapsulation layer covering the electronic element and the plurality of conductive pillars on the insulating layer, wherein the encapsulation layer has a plurality of second vias exposing the plurality of conductive pillars; and filling a plurality of conductive materials in the plurality of second vias and allowing the plurality of conductive materials partially protrude from the encapsulation layer.

In one embodiment of the aforementioned electronic package and method, each of the plurality of conductive pillars has a first pillar body and a second pillar body connected to the first pillar body, the first pillar body is formed in each of the first vias, the second pillar body is embedded in the encapsulation layer and protruding from the insulating layer.

In one embodiment of the aforementioned electronic package and method, a height of the second pillar body protruding from the insulating layer is equal to or less than a height of the electronic element disposed on the insulating layer.

In one embodiment of the aforementioned electronic package and method, a size of the second pillar body is larger than a size of each of the second vias.

In one embodiment of the aforementioned electronic package and method, a depth of each of the second vias is less than a thickness of the encapsulation layer.

As can be understood from the above, in the electronic package and manufacturing method thereof of the present disclosure, the second vias are formed in the encapsulation layer and exposing the conductive pillars protruding from the insulating layer, and the second vias are filled with the conductive materials, such that the gap between the electronic device and the encapsulation layer of a package structure can be reduced, which facilitates thinning the overall thickness of the electronic package.

### BRIEF DESCRIPTION OF THE DRAWINGS

FIG. 1 is a schematic cross-sectional view of a conventional electronic package.

FIG. 2A to FIG. 2G are schematic cross-sectional views of the first embodiment of the manufacturing method of the electronic package according to the present disclosure.

FIG. 3A to FIG. 3G are schematic cross-sectional views of the second embodiment of the manufacturing method of the electronic package according to the present disclosure.

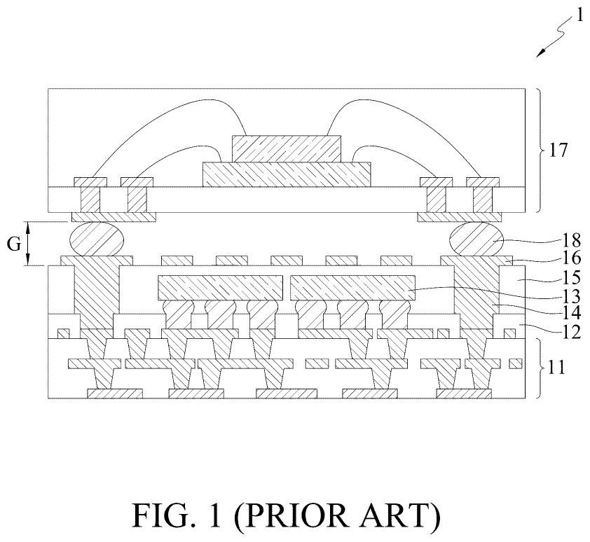

### DETAILED DESCRIPTION

Embodiments of the present disclosure are described below by specific examples.

Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

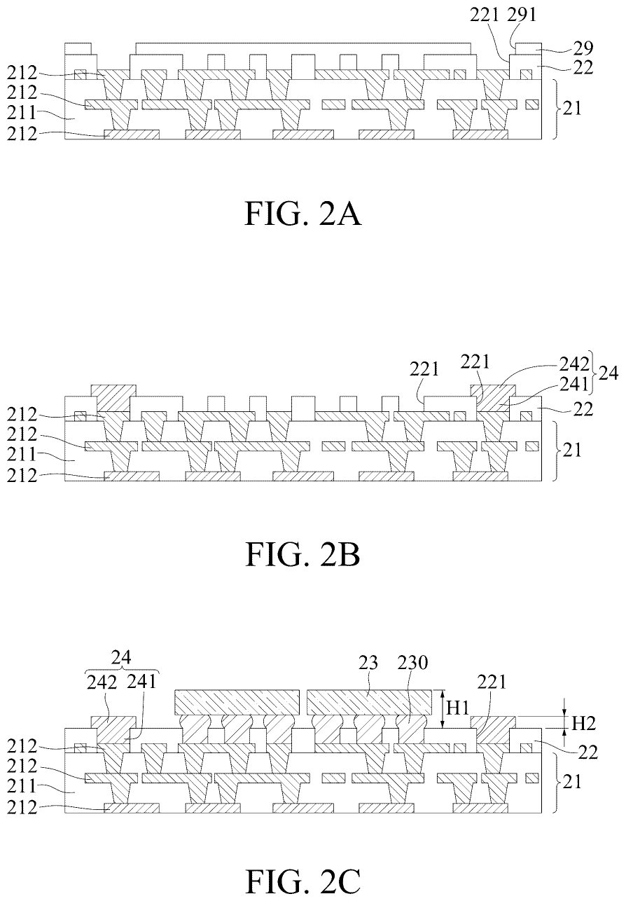

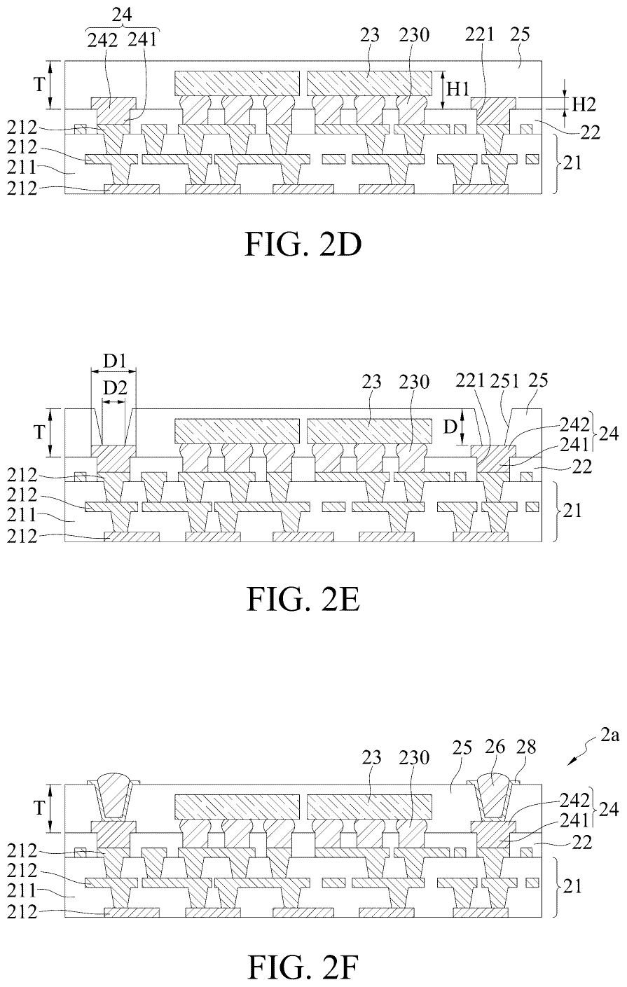

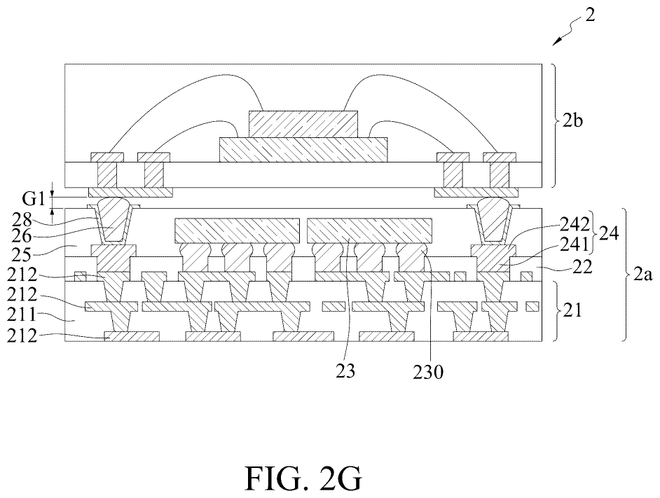

FIG. 2A to FIG. 2G are schematic cross-sectional views of the first embodiment of the manufacturing method of the electronic package according to the present disclosure.

As shown in FIG. 2A, a circuit structure 21 is provided, which includes a plurality of dielectric layers 211 and a plurality of circuit layers 212 bonded to the plurality of dielectric layers 211, wherein an outermost dielectric layer 211 can be used as a solder mask layer, and an outermost circuit layer 212 is exposed out from the solder mask layer to serve as an electrical contact pad. Further, relative to the outermost circuit layer 212, an innermost circuit layer 212 (i.e., the bottom side of the circuit structure 21 in FIG. 2A) is embedded in the dielectric layer 211 and is flush with a surface of the dielectric layer 211 of the bottom side of the circuit structure 21. Therefore, the circuit structure 21 in this embodiment according to the present disclosure can be an embedded circuit substrate.

Next, an insulating layer 22 having a plurality of first vias 221 is disposed on the outermost dielectric layer 211, and a barrier layer 29 having a plurality of through holes 291 is disposed on the insulating layer 22.

In this embodiment, the circuit structure 21 can be a coreless substrate structure, the circuit layer 212 adopts a circuit redistribution layer (RDL) specification, and the dielectric layer 211 is an ajinomoto build-up film (ABF) dielectric material, in which coefficient of thermal expansion (CTE) thereof is 13 to 17 ppm/° C.

Furthermore, a material of the insulating layer 22 can be a photo-imageable dielectric layer (PID), specifically, it can be photosensitive polyimide (PSPI), with a CTE of 30 to 35 ppm/° C. Therefore, exposure and development can be used to form a plurality of first vias 221, and the first via 221 exposes part of the circuit layer 212.

Also, a material of the barrier layer 29 is dried film or other photoresist aspects and is formed on the insulating layer 22 through spin coating or lamination, and the plurality of through holes 291 are formed in a manner of exposure and development. The plurality of through holes 291 are correspondingly connected to part of the plurality of first through holes 221, and a width of the through hole 291 is greater than a width of the first via 221.

As shown in FIG. 2B, a metal material (such as copper) is formed in the through hole 291 and the first via 221 in a manner of plating or sputtering to serve as a conductive pillar 24, and then the barrier layer 29 is removed to expose part of the first via 221.

In this embodiment, the conductive pillar 24 has a first pillar body 241 and a second pillar body 242 connected to the first pillar body 241. The first pillar body 241 is formed in the first via 221 and electrically connected to the outermost circuit layer 212. The second pillar body 242 is formed on the first pillar body 241 and the insulating layer 22 and protrudes from and covers the top surface of the insulating layer 22.

As shown in FIG. 2C, at least one electronic element 23 is disposed on the insulating layer 22 and electrically connected to the circuit layer 212 through the conductive bumps 230 disposed in the plurality of first vias 221 that expose part of the circuit layer 212. A height H2 of the second pillar body 242 protruding from the insulating layer 22 is smaller than a height H1 of the electronic element 23 disposed on the insulating layer 22.

In this embodiment, the electronic element 23 is an active element, an inactive element, or a combination thereof. The active element is such as a semiconductor chip, and the inactive element is such as a resistor, a capacitor, or an inductor. The conductive bump 230 is, for example, a solder material (solder paste or solder ball).

As shown in FIG. 2D, an encapsulation layer 25 is formed on the insulating layer 22 to cover the electronic elements 23, the plurality of second pillar bodies 242 and the conductive bumps 230, wherein a thickness T of the encapsulation layer 25 is greater than the height H2 of the second pillar body 242 protruding from the insulating layer 22, and is greater than the height H1 of the electronic element 23 disposed on the insulating layer 22. The encapsulation layer 25 is an insulating material, such as polyimide (PI), dry film, encapsulating of epoxy resin or other molding compounds, which can be formed on the insulating layer 22 in a manner of lamination or molding.

As shown in FIG. 2E, partial material of the encapsulation layer 25 is removed in a manner of laser to form a plurality of second vias 251 that expose the top surfaces of the plurality of second pillar bodies 242, wherein a thickness T of the encapsulation layer 25 is greater than a depth D of the second via 251, and a size D2 of the second via 251 is smaller than a size D1 of the second pillar body 242, so that the second pillar body 242 can only be partially exposed, for example, only the upper surface of the second pillar body 242 can only be partially exposed.

As shown in FIG. 2F, a metal layer 28 is formed on the bottom surface and side surfaces in the second via 251 and on part of the encapsulation layer 25 by chemical coating. The metal layer 28 can be made of copper, for example, and is electrically connected to the second pillar body 242. Next, on the metal layer 28 in the second via 251 can be filled with a conductive material 26, and the conductive material 26 partially protrudes from the top surface of the encapsulation layer 25, thereby obtaining a package structure 2a. It should be understood that the metal layer 28 may not be formed, but rather be a direct filling of the second via 251 with the conductive material 26.

In this embodiment, the conductive material 26 may be, for example, a solder paste.

As shown in FIG. 2G, a heating operation such as a reflow process can be performed to reflow the conductive materials 26, so that an electronic device 2b can be connected to the package structure 2a through the plurality of conductive materials 26, thereby obtaining electronic package 2, with a gap G1 between the electronic device 2b and the encapsulation layer 25 of the package structure 2a. In one embodiment, the electronic device 2b is a ball grid array (BGA) semiconductor package or a wire bond (WB) semiconductor package, including but not limited to.

In view of the above, in the electronic package 2, the second vias 251 exposing the conductive pillars 24 are formed in the encapsulation layer 25, and the second vias 251 are filled with the conductive material 26, and the package structure 2a is connected to the electronic device 2b by reflowing the conductive material 26, such that the gap G1 between the electronic device 2b and the encapsulation layer 25 of the package structure 2a can be reduced (that is, it is smaller than the gap G between the electronic device 17 and the encapsulation layer 15 in the prior art), which facilitates thinning the overall thickness of the electronic package 2.

In addition, the first via 221 is formed in the insulating layer 22 in a manner of exposure and development, so that it is not limited to the aspect ratio of laser drilling, which facilitates the fabrication of the conductive pillars 24. The conductive pillars 24 can be exposed without grinding the encapsulation layer 25, and the conductive pillars 24 interconnected with the conductive material 26 can provide a larger surface area, which facilitates the adhesion between the conductive material 26 and the conductive pillars 24, and can prevent cracks from causing reliability issues.

Furthermore, the dielectric layer 211 is composed of ABF, and the CTE of the insulating layer 22 is greater than the CTE of the dielectric layer 211 (that is, the CTE gradually increases from bottom to top), which helps to reduce warpage during the reflow process and avoid risks such as solder ball peeling, cracks or displacement after packaging.

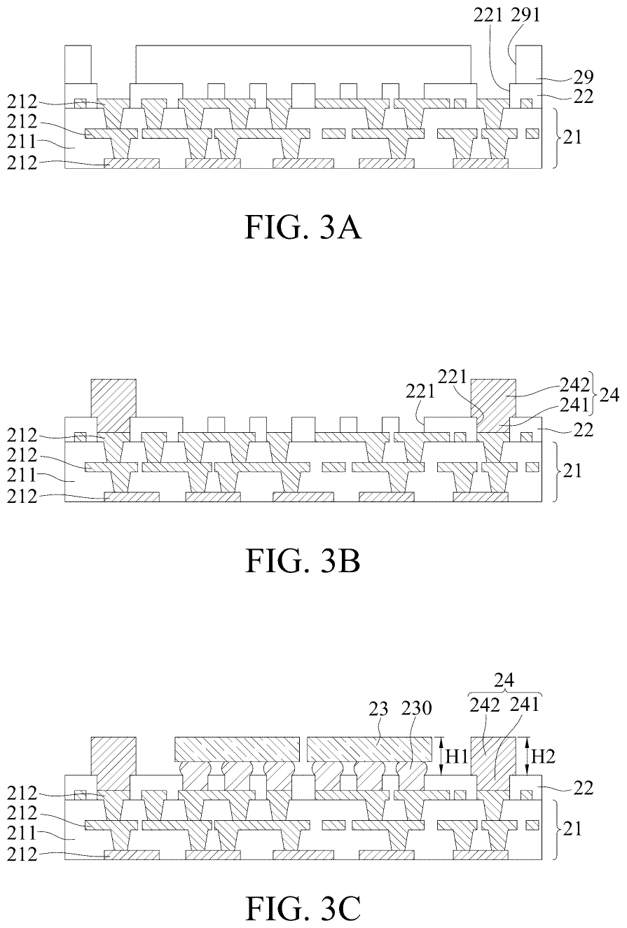

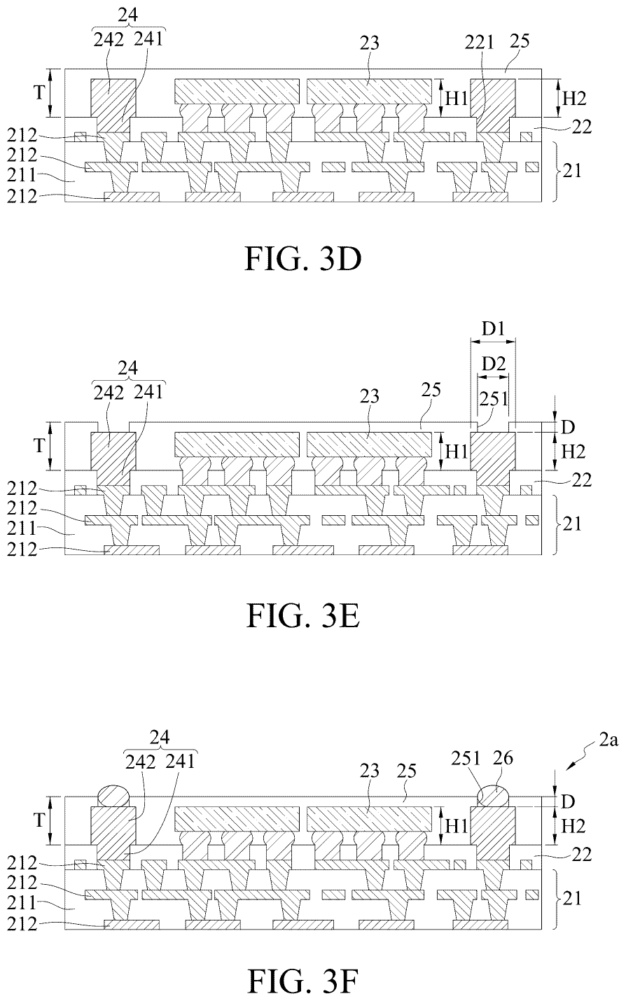

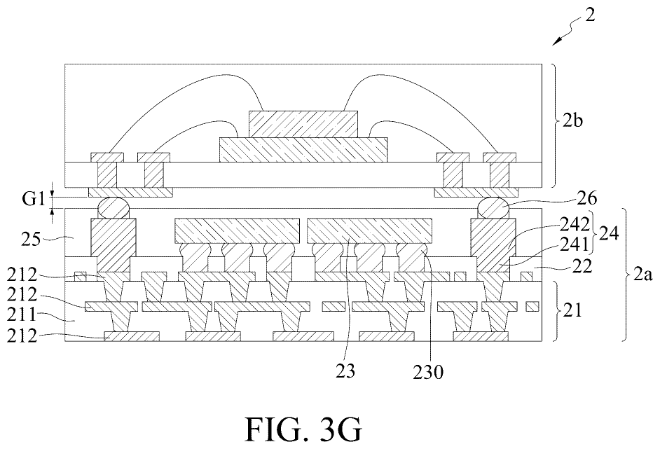

FIG. 3A to FIG. 3G are schematic cross-sectional views of a second embodiment of a manufacturing method of an electronic package according to the present disclosure. The second embodiment is different from the aforementioned first embodiment only in part of the manufacturing method. The differences are described below, and the same technical content will not be repeated here.

As shown in FIG. 3A, a circuit structure 21 is provided, which includes a plurality of dielectric layers 211 and a plurality of circuit layers 212 bonded to the plurality of dielectric layers 211, wherein an outermost dielectric layer 211 can be used as a solder mask layer, and an outermost circuit layer 212 is exposed out from the solder mask layer to serve as an electrical contact pad. Next, an insulating layer 22 having a plurality of first vias 221 is disposed on the outermost dielectric layer 211, and a barrier layer 29 having a plurality of through holes 291 is disposed on the insulating layer 22. In this embodiment, a thickness of the barrier layer 29 is greater than that of the barrier layer 29 in the first embodiment.

As shown in FIG. 3B, a metal material (such as copper) is formed in the through hole 291 and the first via 221 in a manner of plating or sputtering to serve as a conductive pillar 24, and the barrier layer 29 is removed to expose part of the first via 221.

In this embodiment, the conductive pillar 24 has a first pillar body 241 and a second pillar body 242 connected to the first pillar body 241. The first pillar body 241 is formed in the first via 221 and electrically connected to the outermost circuit layer 212. The second pillar body 242 is formed on the first pillar body 241 and the insulating layer 22 and protrudes from the top surface of the insulating layer 22.

As shown in FIG. 3C, at least one electronic element 23 is disposed on the insulating layer 22 and electrically connected to the circuit layer 212 through a plurality of conductive bumps 230 disposed in the first vias 221, so that a height H2 of the second pillar body 242 protruding from the insulating layer 22 is equal to a height H1 of the electronic element 23 disposed on the insulating layer 22.

As shown in FIG. 3D, an encapsulation layer 25 is formed on the insulating layer 22 to cover the electronic elements 23 and the plurality of second pillar bodies 242, wherein a thickness T of the encapsulation layer 25 is greater than the height H2 of the second pillar body 242 protruding from the insulating layer 22, and is greater than the height H1 of the electronic element 23 disposed on the insulating layer 22.

As shown in FIG. 3E, partial material of the encapsulation layer 25 is removed in a manner of laser to form a plurality of second vias 251 that expose the top surfaces of the plurality of second pillar bodies 242, wherein the thickness T of the encapsulation layer 25 is greater than a depth D of the second via 251, and a size D2 of the second via 251 is smaller than a size D1 of the second pillar body 242, so that the second pillar body 242 can only be partially exposed, for example, the upper surface of the second pillar body 242 is partially exposed.

As shown in FIG. 3F, the second via 251 is filled with conductive material 26, and the conductive material 26 partially protrudes from the top surface of the encapsulation layer 25, thereby obtaining a package structure 2a. In this embodiment, the conductive material 26 may be, for example, a solder paste.

As shown in FIG. 3G, a heating operation such as a reflow process can be performed to reflow the conductive materials 26, so that an electronic device 2b can be connected to the package structure 2a through the plurality of conductive materials 26, thereby obtaining electronic package 2. A gap G1 is between the electronic device 2b and the encapsulation layer 25 of the package structure 2a, and the gap G1 is smaller than the gap G between the electronic device 17 and the encapsulation layer 15 in the prior art, which facilitates thinning the overall thickness of the electronic package 2.

The present disclosure provides an electronic package 2, which includes a circuit structure 21, an insulating layer 22, at least one electronic element 23, a plurality of conductive pillars 24, an encapsulation layer 25, a plurality of conductive materials 26 and an electronic device 2b.

The circuit structure 21 includes a plurality of dielectric layers 211 and a plurality of circuit layers 212 bonded to the plurality of dielectric layers 211, wherein an outermost dielectric layer 211 can be used as a solder mask layer, and an outermost circuit layer 212 is exposed out from the solder mask layer to serve as an electrical contact pad.

The insulating layer 22 is disposed on the outermost dielectric layer 211 and has a plurality of first vias 221 exposing the outermost circuit layer 212.

At least one electronic element 23 is disposed on the insulating layer 22 and electrically connected to the circuit layer 212 through a plurality of conductive bumps 230 disposed in the first vias 221.

A plurality of conductive pillars 24 are formed in a plurality of first vias 221 and partially protrude from the insulating layer 22. In this embodiment, the conductive pillar 24 has a first pillar body 241 and a second pillar body 242 connected to the first pillar body 241. The first pillar body 241 is formed in the first via 221 and is electrically connected to the outermost circuit layer 212. The second pillar body 242 is formed on the first pillar body 241 and the insulating layer 22 and protrudes from the top surface of the insulating layer 22.

In one embodiment, a height H2 of the second pillar body 242 protruding from the insulating layer 22 is smaller than a height H1 of the electronic element 23 disposed on the insulating layer 22. In another embodiment, the height H2 of the second pillar body 242 protruding from the insulating layer 22 is equal to the height H1 of the electronic element 23 disposed on the insulating layer 22.

The encapsulation layer 25 is formed on the insulating layer 22, covers the electronic element 23 and the plurality of conductive pillars 24, and has a plurality of second vias 251 exposing the plurality of conductive pillars 24, wherein a thickness T of the encapsulation layer 25 is greater than the height H2 of the second pillar body 242 protruding from the insulating layer 22, is greater than the height H1 of the electronic element 23 disposed on the insulating layer 22, and is greater than a depth D of the second via 251, and a size D2 of the second via 251 is smaller than a size D1 of the second pillar body 242, so that the second pillar body 242 can only be partially exposed.

The plurality of second vias 251 are filled with the plurality of conductive materials 26, which partially protrude from the encapsulation layer 25, thereby obtaining a package structure 2a.

In one embodiment, a metal layer 28 can be formed on a side surface of the second via 251 and part of the encapsulation layer 25, and on the metal layer 28 of the second via 251 can be filled with the conductive material 26. In another embodiment, the metal layer 28 may not be formed, but may directly fill the second via 251 with the conductive material 26.

An electronic device 2b can be connected to the package structure 2a through the plurality of conductive materials 26, thereby obtaining the electronic package 2 in this embodiment according to the present disclosure.

In view of the above, in the electronic package and manufacturing method thereof according to the present disclosure, the second vias are formed in the encapsulation layer and expose the conductive pillars, and the second vias are filled with the conductive materials, such that the gap between the electronic device and the encapsulation layer of a package structure can be reduced, which facilitates thinning the overall thickness of the electronic package. In addition, the vias are formed in a manner of exposure and development, so that it is not limited to the aspect ratio of laser drilling, which facilitates the fabrication of the conductive pillars, the adhesion between the conductive materials and the conductive pillars, and avoids the problem of warpage. Also, the CTEs of the dielectric layer and the insulating layer gradually increase from bottom to top, which helps to reduce warpage during the reflow process and avoid risks such as solder ball peeling, cracks or displacement after packaging.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a circuit structure having a circuit layer;
an insulating layer disposed on the circuit structure and having a plurality of first vias exposing the circuit layer;
an electronic element disposed on the insulating layer and electrically connected to the circuit structure;
a plurality of conductive pillars formed in the plurality of first vias and partially protruding from the insulating layer;
an encapsulation layer formed on the insulating layer and covering the electronic element and the plurality of conductive pillars, the encapsulation layer having a plurality of second vias exposing the plurality of conductive pillars; and
a plurality of conductive materials filled in the plurality of second vias and partially protruding from the encapsulation layer.

2. The electronic package of claim 1, wherein each of the plurality of conductive pillars has a first pillar body and a second pillar body connected to the first pillar body, the first pillar body is formed in each of the first vias, and the second pillar body is embedded in the encapsulation layer and protrudes from the insulating layer.

3. The electronic package of claim 2, wherein a height of the second pillar body protruding from the insulating layer is equal to or less than a height of the electronic element disposed on the insulating layer.

4. The electronic package of claim 2, wherein a size of the second pillar body is larger than a size of each of the second vias.

5. The electronic package of claim 1, wherein a depth of each of the second vias is less than a thickness of the encapsulation layer.

6. A method of manufacturing an electronic package, comprising:
providing a circuit structure with a circuit layer;
forming an insulating layer on the circuit structure, wherein the insulating layer has a plurality of first vias exposing the circuit layer;
forming a plurality of conductive pillars in the plurality of first vias, and disposing an electronic element on the insulating layer, so that the plurality of conductive pillars partially protrude from the insulating layer, and the electronic element is electrically connected to the circuit structure;
forming an encapsulation layer covering the electronic element and the plurality of conductive pillars on the insulating layer, wherein the encapsulation layer has a plurality of second vias exposing the plurality of conductive pillars; and
filling a plurality of conductive materials in the plurality of second vias and allowing the plurality of conductive materials partially protrude from the encapsulation layer.

7. The electronic package of claim 6, wherein each of the plurality of conductive pillars has a first pillar body and a second pillar body connected to the first pillar body, the first pillar body is formed in each of the first vias, the second pillar body is embedded in the encapsulation layer and protrudes from the insulating layer.

8. The electronic package of claim 7, wherein a height of the second pillar body protruding from the insulating layer is equal to or less than a height of the electronic element disposed on the insulating layer.

9. The electronic package of claim 7, wherein a size of the second pillar body is larger than a size of each of the second vias.

10. The electronic package of claim 6, wherein a depth of each of the second vias is less than a thickness of the encapsulation layer.
